(19) United States
(12) Patent Application Publication
(10) Pub. No.: US 2025/0370050 A1
(43) Pub. Date: Dec. 4, 2025

(54) DETECTION OF OPEN WIRES IN BATTERY MODULES

(71) Applicant: Rivian IP Holdings, LLC, Irvine, CA (US)

(72) Inventors: Kishore Kumar SUKUMAR, San Jose, CA (US); Vasant Kumar EASWARAN, Frisco, TX (US); Nabarun DAS, Troy, MI (US); Tejas Abhay CHAFEKAR, Edwards, IL (US)

(21) Appl. No.: 19/059,066

(22) Filed: Feb. 20, 2025

Related U.S. Application Data
(60) Provisional application No. 63/652,598, filed on May 28, 2024.

(51) Int. Cl. G01R 31/3835; B60L 58/18; G01R 31/54

(52) U.S. Cl. CPC G01R 31/3835; B60L 58/18; G01R 31/54

(57) ABSTRACT

Methods, apparatuses, or systems may be used to detect open wire faults in battery modules, such as in electric vehicles. Methods, apparatuses, or systems may include comparing voltage measurements of even and odd battery cells with pull-up resistances enabled and disabled. By taking simultaneous measurements and determining comparisons between adjacent cells, the method may compensate for load variations that may lead to false detections. The approach may be executed within a fault tolerant time interval that allows for timely safety measures to be implemented when a fault is detected.

### CROSS REFERENCE TO RELATED APPLICATION(S)

The present application claims the benefit of U.S. Provisional Application No. 63/652,598, entitled “DETECTION OF OPEN WIRES IN BATTERY MODULES”, filed May 28, 2024, the entirety of which is incorporated herein for reference.

### INTRODUCTION

This application is directed to open wire detection and more particularly, detection of open wire faults associated with batteries.

### SUMMARY

The disclosed subject matter may include methods, systems, or apparatuses for detecting open wire faults in battery modules, such as in electric vehicles. In an example, a method for detecting open wire faults may include receiving voltage measurements from even and odd battery cells at the same time period, with pull-up resistance enabled for one set of cells (even or odd) and disabled for the other. The method may then determine a relationship (e.g., ratio) of these voltage measurements and compare it to a predefined threshold. If the relationship falls within the threshold, an indication of an open wire fault may be transmitted.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates an example block diagram of battery cells.

FIG. 2 illustrates an example method associated with baseline measurements for open wire fault detection.

FIG. 3A illustrates example sequence diagram associated with baseline measurements for open wire fault detection.

FIG. 3B illustrates example sequence diagram associated with baseline measurements for open wire fault detection and may continue the sequence of FIG. 3A.

FIG. 3C illustrates example sequence diagram associated with baseline measurements for open wire fault detection and may continue the sequence of FIG. 3B.

FIG. 4A illustrates example method for open wire fault detection associated with enabled and non-enabled pull-ups.

FIG. 4B illustrates example method for open wire fault detection associated with enabled and non-enabled pull-ups.

FIG. 5A illustrates example sequence diagram associated with measurement of pull-up resistance enabled on even cells for open wire fault detection.

FIG. 5B illustrates example sequence diagram associated with measurement of pull-up resistance enabled on odd cells for open wire fault detection and may continue the sequence of FIG. 5A.

FIG. 6 illustrates an example side view of a vehicle.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

Electric vehicles may incorporate large batteries with ability to drive various high loads (drawing high currents) related to automotive electronics, motors, drivetrain, heat pumps, or heating, ventilation, and air conditioning (HVAC), among other things. While these loads are driven, if the load profile changes significantly in a short period of time, droops and spikes are seen on the supplied battery voltage. If these droops and spikes are observed at the same time when pull-ups are enabled to detect open wire fault detection, then this may lead to false positives (droop higher than threshold) and true negatives (spike compensates for the excepted droop with pull-up enabled). For safety critical usage of the battery (at high automotive safety integrity level (ASIL)), open wire faults between the battery cells to the monitoring circuit should be diagnosed within the fault tolerant time interval (FTTI) to take a safe state. In an example, the disclosed subject matter provides methods, apparatuses, or systems for determining open wire faults based on a comparison of voltage measured for even cells when pull up is enabled with voltage measured for odd cells when pull up is not enabled in the same time interval. This approach may reduce or eliminate the need for performing some load profiles or base measurements.

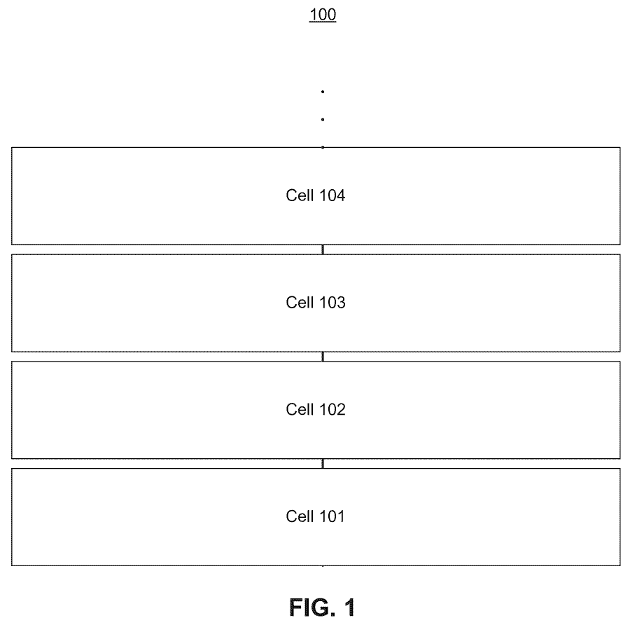

FIG. 1 illustrates an example block diagram of battery cells, which may be within an electric vehicle. Battery pack 100 may include a plurality of cells (e.g., 12, 16, 18, 24, or more cells in pack 100). As shown, pack 100 may include cell 101, cell 102, cell 103, or cell 104, among others. The plurality of battery cells may be serially connected within pack 100 and as further described herein may be monitored using one or more application-specific integrated circuits (ASICs).

ASICs may be used to measure voltage for methods that may incorporate pull-up resistance to detect open wire faults. In an example implementation, a pull-up resistance between the cell voltage or the input line to the supply voltage or pull down to the ground may be enabled and then a variation in the battery cell voltage may be measured. And based on these voltage variations, open wire faults may be detected. Yet using certain methods, if the load profile changes significantly (e.g., different combination and intensity of loads while driving), then the reliability of open wire fault detection is in question, which may include false positives.

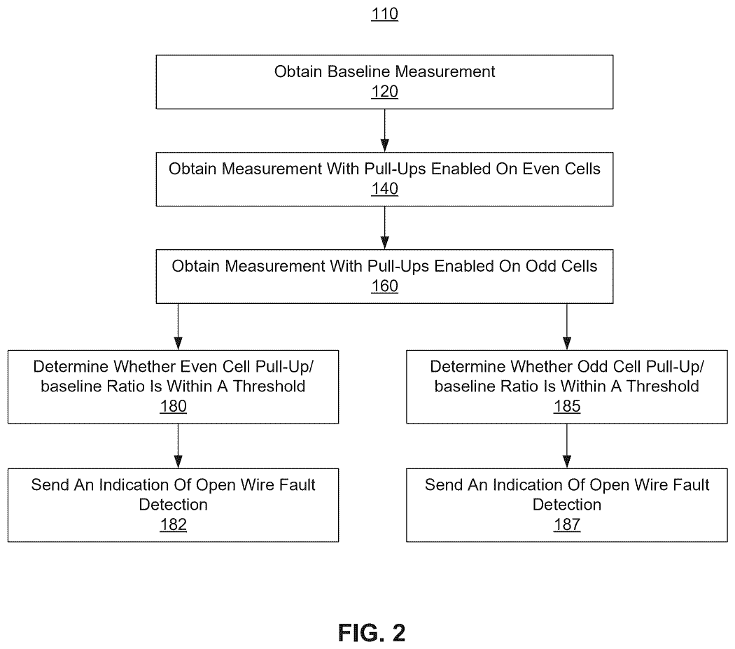

FIG. 2 illustrates an example method 110 for open wire fault detection that may use comparisons to baseline measurements. Table 1 provides additional context to method 110. At block 120, baseline measurements (e.g., voltage measurements) are obtained at a first time period (t1), in which pull-up resistances are disabled for cell 101 and cell 102 during t1. Therefore, in this example, cell 101 may have voltage measured in which pull-up resistances (also referred herein as pull-ups) are disabled and cell 102 may have voltage measured in which pull-ups are disabled.

At block 140, measurements with pull-ups enabled on even cells (e.g., cell 102 of pack 100, among others) at a second time period (t2) may be obtained. At block 160, measurements with pull-ups enabled on odd cells (e.g., cell 101 of pack 100, among others) at a third time period (t3) may be obtained.

TABLE 1

| | | Cell #102 | Cell #101 |
|---|---|---|---|
| Steps | Category | measurements | measurements |
| 1 | Baseline measure- | V_{102.ADC.wo.PU} | V_{101.ADC.wo.PU} |
| | ment (all pull-ups | | |
| | disabled) | | |
| 2 | Measurement with | V_{102.ADC.w.PU} | |
| | even channel pull-up | | |
| | enabled | | |
| 3 | Measurement with | | V_{101.ADC.w.PU} |
| | odd channel pull-up | | |
| | enabled | | |
| 4 | Open wire fault detection criteria - | $\frac{{V}_{102. ADC . wo . PU}}{{V}_{102. ADC . w . PU}} < 15 \%$ | $\frac{{V}_{101. ADC . wo . PU}}{{V}_{101. ADC . w . PU}} < 15 \%$ |
| | FALSE | | |
| | Open wire fault detection criteria - | $\frac{{V}_{102. ADC . wo . PU}}{{V}_{102. ADC . w . PU}} \geq 15 \%$ | $\frac{{V}_{101. ADC . wo . PU}}{{V}_{101. ADC . w . PU}} \geq 15 \%$ |
| | TRUE | | |

At block 180, the relationship (e.g., ratio) of baseline measurement of block 120—cell 102 (without pull-ups) and pull-up enabled measurement of block 140—cell 102 is within a threshold may be determined. The threshold may be greater than or equal to 15% (other values are contemplated and this is just an example) and the threshold may have been determined based on a load profile (as further described herein). In an example with regard to determining the threshold it may be composed of typical value and tolerance. In this instance, there may be a 10% typical value+5% tolerance. The 10% typical value may be based on the value of internal pull-up resistance and the input resistance of analog-to-digital converter (ADC) inside the ASIC. The value may be different on ASICs from different suppliers. The 5% tolerance may be based on the load profile and component variations. The threshold, as disclosed in more detail herein, may be difficult to set based on various types of loads that may function in a system (e.g., vehicle 300). At block 182, based on being within the threshold with regard to block 180, an indication of an open wire fault detection for cell 102 may be sent.

At block 185, the relationship (e.g., ratio) of baseline measurement of block 120—cell 101 (without pull-ups) and pull-up enabled measurement of block 160—cell 101 is within a threshold may be determined. The threshold may be greater than or equal to 15% and the threshold may have been determined based on a load profile (as further described herein). At block 187, based on being within the threshold with regard to block 185, an indication of an open wire fault detection for cell 101 may be sent. After an indication of an open wire fault, there may be different actions that may be taken, such as transmitting an audio, visual, or haptic alert to the driver, determine if the vehicle is in a safe operating condition, halt the vehicle within a certain time frame, among other things.

Method 110 may lead to false positives if the loads of the electric vehicle changes significantly in between the time periods of measurements (e.g., between t1, t2, or t3). False positives may lead to inefficient use of time and resources. For example, although the vehicle may be in a safe state, because of false positive alerts, use of the vehicle may be halted and therefore there is loss in availability of the vehicle, even though there is no fault.

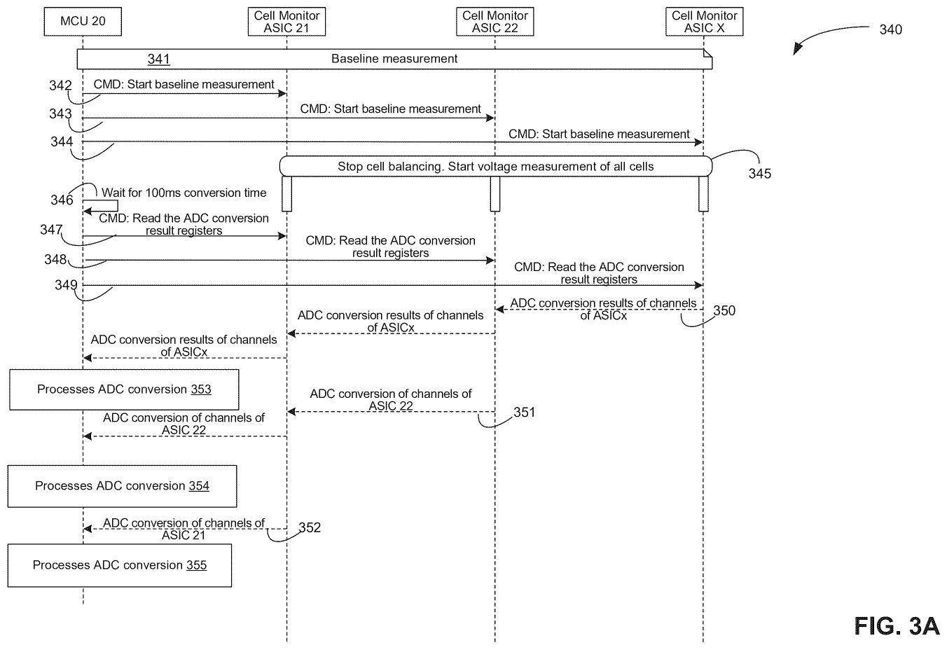

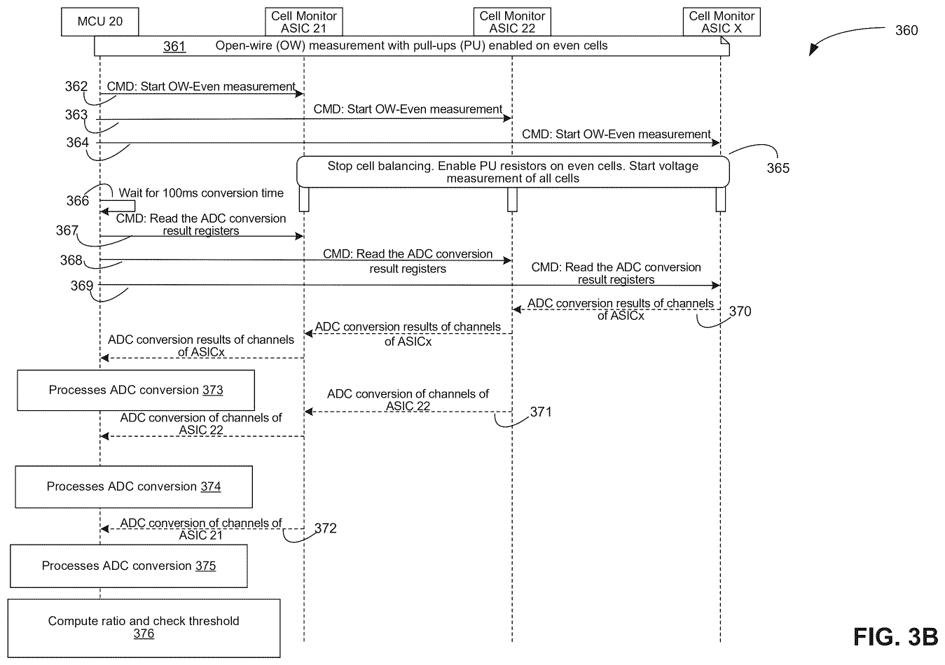

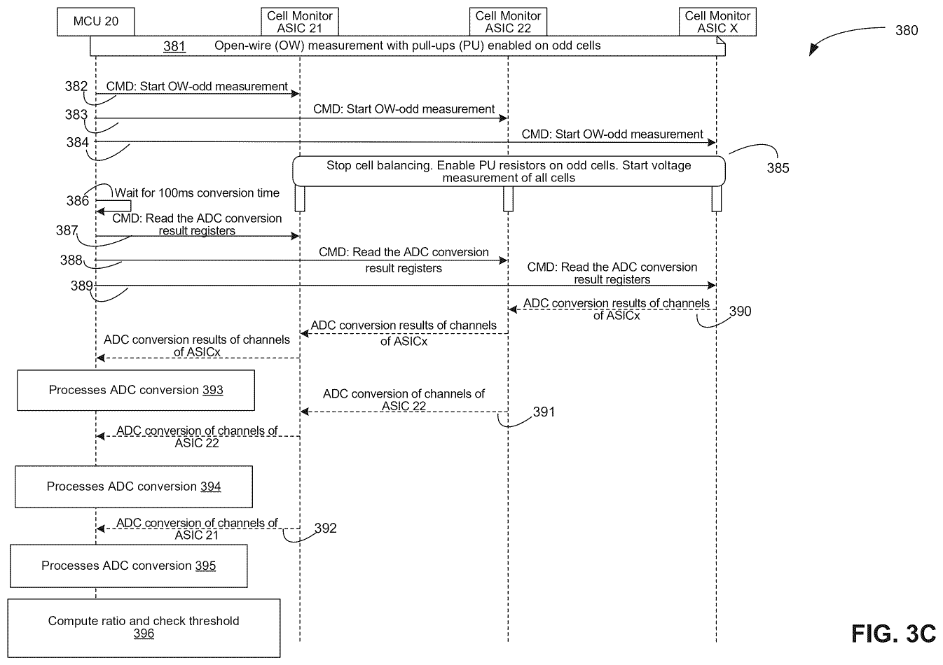

FIG. 3A-FIG. 3C illustrate example sequence diagrams for the subject matter of FIG. 2 (method 110). As shown in FIG. 3A, baseline measurement steps may be taken in which microcontroller unit (MCU) 20 communicates with one or more cell monitor ASICs as indicated. As shown in FIG. 3B, open wire (OW) measurement steps with pull-ups (PUs) on even cells may be executed. In FIG. 3B, MCU 20 communicates with one or more cell monitor ASICs as indicated and MCU 20 may determine ratios and check thresholds as shown in Table 1. As shown in FIG. 3C, OW measurement steps with pull-ups (PUs) on odd cells may be executed. In FIG. 3C, MCU 20 communicates with one or more cell monitor ASICs as indicated and MCU 20 may determine ratios and check thresholds as shown in Table 1.

FIG. 3A illustrates an example sequence diagram 340 associated with baseline measurements for open wire fault detection. At step 341, the sequence begins with the Microcontroller Unit (MCU) 20 initiating the baseline measurement process. At step 342, MCU 20 sends a command to start baseline measurement to Cell Monitor ASIC 21. At step 343, MCU 20 sends a similar command to start baseline measurement to Cell Monitor ASIC 22. At step 344, MCU 20 sends the start baseline measurement command to Cell Monitor ASIC X, representing any additional ASICs in the system. At step 345, upon receiving these commands, the Cell Monitor ASICs stop cell balancing operations and start voltage measurement of cells approximately simultaneously. At step 346, the system waits for a period (e.g., 100 ms) conversion time to allow for accurate voltage measurements. At step 347, after the conversion time, MCU 20 sends a command to read the ADC conversion result registers to Cell Monitor ASIC 21. At step 348, MCU 20 sends a similar command to read the ADC conversion result registers to Cell Monitor ASIC 22. At step 349, MCU 20 sends the command to read the ADC conversion result registers to Cell Monitor ASIC X. At step 350, Cell Monitor ASIC X responds by sending the ADC conversion results of its channels to MCU 20. At step 351, Cell Monitor ASIC 22 sends its ADC conversion results of channels to MCU 20. At step 352, Cell Monitor ASIC 21 sends its ADC conversion results of channels to MCU 20. At step 353, MCU 20 receives and processes the ADC conversion results from ASIC 21. At step 354, MCU 20 receives and processes the ADC conversion results from ASIC 22. At step 355, MCU 20 receives and processes the ADC conversion results from other ASICs X for the baseline measurement process.

FIG. 3B illustrates an exemplary sequence diagram 360 associated with measurements for open wire fault detection with pull-ups enabled on even cells. At step 361, MCU 20 initiates the open-wire (OW) measurement process for even cells. At step 362, MCU 20 sends a command to start OW-Even measurement to Cell Monitor ASIC 21. At step 363, MCU 20 sends a similar command to Cell Monitor ASIC 22. At step 364, MCU 20 sends the start OW-Even measurement command to Cell Monitor ASIC X. At step 365, upon receiving these commands, the Cell Monitor ASICs stop cell balancing and start voltage measurement of cells with pull-ups enabled on even cells, approximately simultaneously. At step 366, the system waits for a period (e.g., 100 ms) conversion time. At step 367, MCU 20 sends a command to read the ADC conversion result registers to Cell Monitor ASIC 21. At step 368, MCU 20 sends a similar command to Cell Monitor ASIC 22. At step 369, MCU 20 sends the command to read ADC conversion result registers to Cell Monitor ASIC X. At step 370, Cell Monitor ASIC X sends its ADC conversion results to MCU 20. At step 371, Cell Monitor ASIC 22 sends its ADC conversion results to MCU 20. At step 372, Cell Monitor ASIC 21 sends its ADC conversion results to MCU 20. At step 373, MCU 20 receives and processes the ADC conversion results from ASIC 21. At step 374, MCU 20 receives and processes the ADC conversion results from ASIC 22. At step 375, MCU 20 receives and processes the ADC conversion results from other ASICs X. At step 376, MCU 20 determine ratios and checks thresholds as shown in Table 1, Step 4.

FIG. 3C illustrates an exemplary sequence diagram 380 associated with measurements for open wire fault detection with pull-ups enabled on odd cells. At step 381, MCU 20 initiates the open-wire (OW) measurement process for odd cells. At step 382, MCU 20 sends a command to start OW-odd measurement to Cell Monitor ASIC 21. At step 383, MCU 20 sends a similar command to Cell Monitor ASIC 22. At step 384, MCU 20 sends the start OW-odd measurement command to Cell Monitor ASIC X. At step 385, upon receiving these commands, the Cell Monitor ASICs stop cell balancing and start voltage measurement of the cells with pull-ups enabled on odd cells. At step 386, the system waits for a period (e.g., 100 ms) conversion time. At step 387, MCU 20 sends a command to read the ADC conversion result registers to Cell Monitor ASIC 21. At step 388, MCU 20 sends a similar command to Cell Monitor ASIC 22. At step 389, MCU 20 sends the command to read ADC conversion result registers to Cell Monitor ASIC X. At step 390, Cell Monitor ASIC X sends its ADC conversion results to MCU 20. At step 391, Cell Monitor ASIC 22 sends its ADC conversion results to MCU 20. At step 392, Cell Monitor ASIC 21 sends its ADC conversion results to MCU 20. At step 393, MCU 20 receives and processes the ADC conversion results from ASIC 21. At step 394, MCU 20 receives and processes the ADC conversion results from ASIC 22. At step 395, MCU 20 receives and processes the ADC conversion results from other ASICs X. At step 396, MCU 20 determine ratios and checks thresholds as shown in Table 1, Step 4.

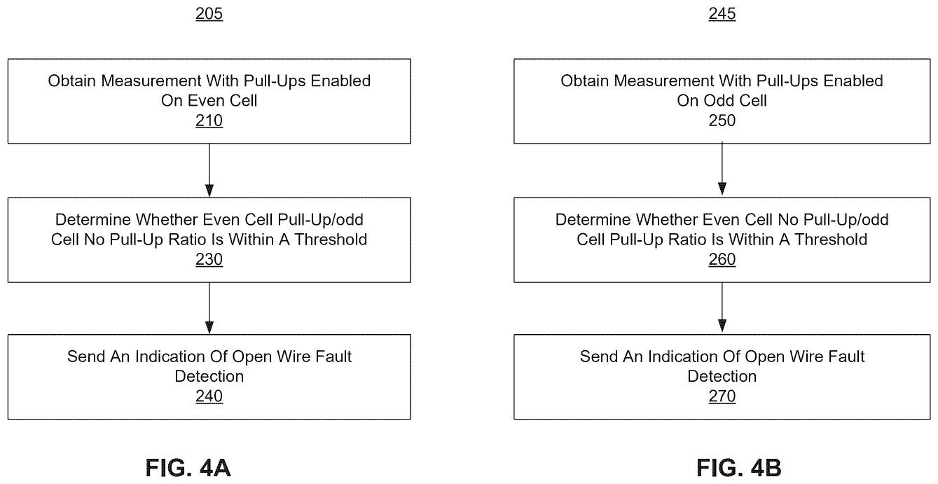

FIG. 4A and FIG. 4B illustrate respective example method 205 and example method 245 for open wire fault detection associated with respective enabled pull-ups and non-enabled pull-ups. Table 2 provides additional context to the methods. With reference to FIG. 4A, at block 210, measurements (e.g., voltage measurements) with pull-ups enabled on even cells (e.g., cell 102 of pack 100, among others) at or near first time period (t1) may be obtained. In addition, measurements with pull-ups not enabled on odd cells (e.g., cell 101 of pack 100, among others) at or near the first time period (t1) (e.g., simultaneous measurements of cells at this step) may be obtained. As the determination uses two measurements happening in parallel (e.g., same time window), it may not be susceptible to load (dI/dt) variations. At block 230, the ratio of enabled pull-up measurement on even cells (e.g., cell 102) and not enabled pull-up measurement of odd cells (e.g., cell 101) is within a threshold may be determined. The threshold may be less than or equal to 0.8 or greater than or equal to 1.2 (e.g., outside the bounds of +/−20% of 1). The threshold may have been determined based on a consideration of one or more tolerances in the battery or circuit design. At block 240, based on being within the threshold with regard to block 230, an indication of an open wire fault detection for cell 102 may be sent. After an indication of an open wire fault, there may be different actions that may be taken, such sending an audio, visual, or haptic alert to the driver, determine if the vehicle is in a safe operating condition, halt the vehicle within a certain time frame, among other things.

With reference to FIG. 4B, at block 250, measurements (e.g., voltage measurements) with pull-ups enabled on odd cells (e.g., cell 101 of pack 100, among others) at or near a second time period (t2) may be obtained. In addition, measurements with pull-ups not enabled on even cells (e.g., cell 102 of pack 100, among others) at or near the second time period (t2) (e.g., simultaneous taking of measurements of cells at this step) may be obtained. As the determination uses two measurements happening in parallel (same time window), it is not susceptible to load (dI/dt) variations. At block 260, the ratio of enabled pull-up measurement on odd cells (e.g., cell 101) and not enabled pull-up measurement of even cells (e.g., cell 102) is within a threshold may be determined. The threshold may be less than or equal to 0.8 or greater than or equal to 1.2 (e.g., outside the bounds of +/−20% of 1). The threshold may have been determined based on a consideration of one or more tolerances in the battery or circuit design. At block 270, based on being within the threshold with regard to block 260, an indication of an open wire fault detection for cell 102 may be sent. One measurement alone (e.g., step 1 or step 3 of Table 2 alone) is sufficient to detect open wire fault detection, but it is contemplated herein that executing both methods (e.g., step 1 and step 3) may allow for a higher integrity level.

TABLE 2

| | | Cell #102 | Cell #101 |
|---|---|---|---|
| Steps | Category | measurements | measurements |
| 1 | Measurement with | V_{102.ADC.w.PU} | V_{101.ADC.wo.PU} |
| | even channel pull-up | | |
| | enabled | | |
| 2 | Open wire fault detection criteria - | $0.8 < \frac{{V}_{102. ADC . w . PU}}{{V}_{101. ADC . wo . PU}} < 1.2$ | |
| | FALSE | | |
| | Open wire fault detection criteria - | $0.8 \geq \frac{{V}_{102. ADC . w . PU}}{{V}_{101. ADC . wo . PU}} \geq 1.2$ | |
| | TRUE | | |
| 3 | Measurement with odd | V_{102.ADC.wo.PU} | V_{101.ADC.w.PU} |
| | channel pull-up enabled | | |
| 4 | Open wire fault detection criteria - | $0.8 < \frac{{V}_{102. ADC . wo . PU}}{{V}_{101. ADC . w . PU}} < 1.2$ | |
| | FALSE | | |
| | Open wire fault detection criteria - | $0.8 \geq \frac{{V}_{101. ADC . wo . PU}}{{V}_{102. ADC . w . PU}} \geq 1.2$ | |
| | TRUE | | |

With continued reference to FIG. 4A and FIG. 4B, instead of having a baseline measurement, which was taken at a different time window (e.g., method 110), pull-up may be enabled on even cell and for odd cell the pull up is not enabled (or vice versa). In addition, measurements of even and odd may occur at the same time and a ratio is determined. Therefore, if there are any significant load variations that occur, the load variation should show up on both of the measurements in the same way and when a ratio is determined any significant variations should be cancelled out. Note the cells of these channels may have dedicated analog to digital converters (ADCs), and therefore there is no multiplexing and the battery cells are measured at the same time period.

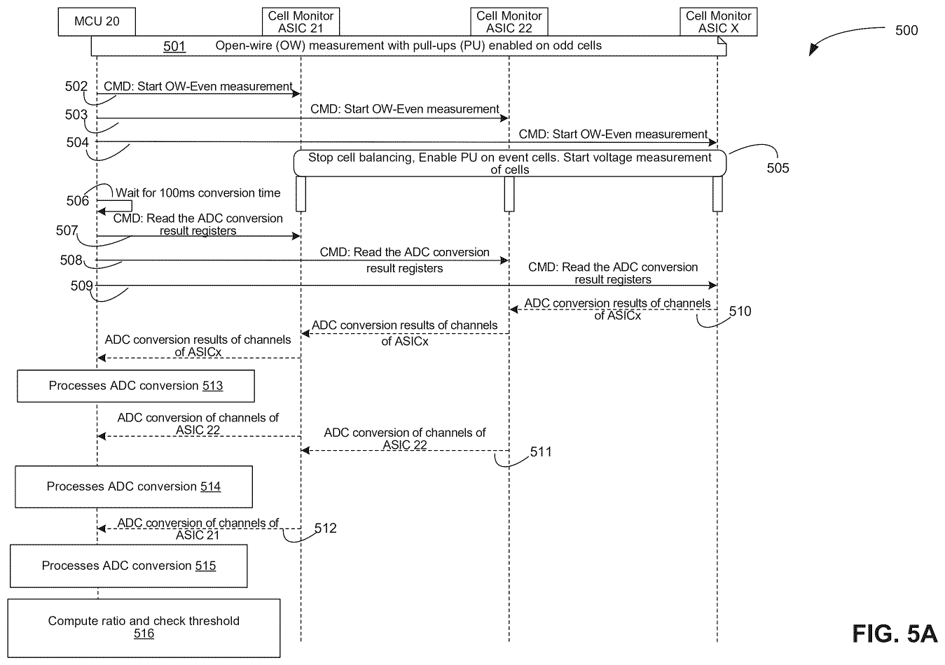

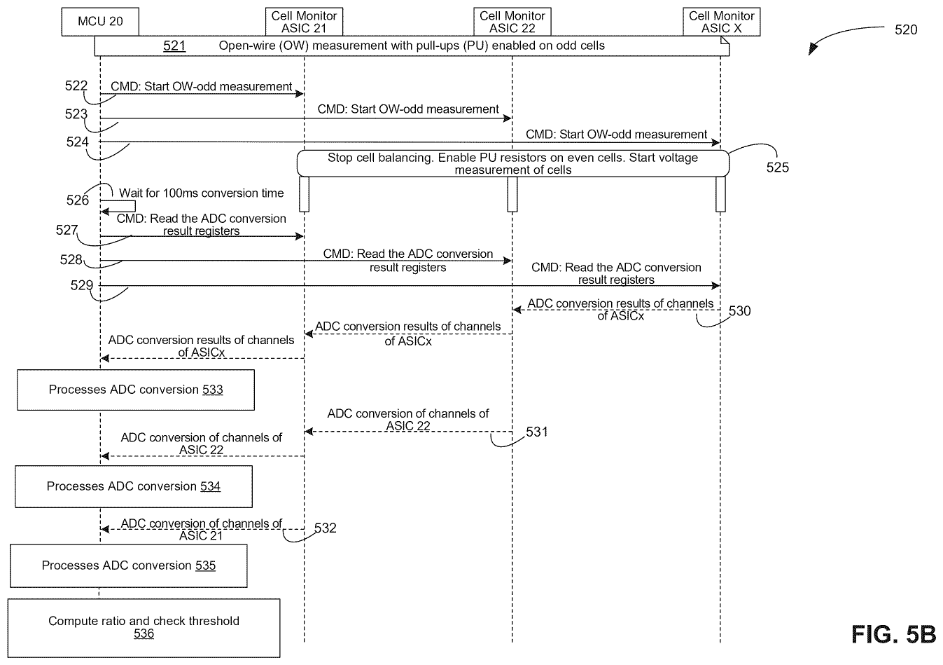

FIG. 5A-FIG. 5B illustrate example sequence diagrams for the subject matter of FIG. 4A or FIG. 4B (e.g., method 205 and method 245). As shown in FIG. 5A, open wire (OW) measurement steps with pull-ups (PUs) on even cells may be executed. In FIG. 5A, MCU 20 communicates with one or more cell monitor ASICs as indicated and MCU 20 may determine ratios and check thresholds as shown in Table 2. As shown in FIG. 5B, OW measurement steps with pull-ups (PUs) on odd cells may be executed. In FIG. 5B, MCU 20 communicates with one or more cell monitor ASICs as indicated and MCU 20 may determine ratios (e.g., relationships) and check thresholds as shown in Table 2.

FIG. 5A illustrates an exemplary sequence diagram 500 associated with measurement of pull-up resistance enabled on even cells for open wire fault detection. At step 501, MCU 20 initiates the open-wire (OW) measurement process for even cells. At step 502, MCU 20 sends a command to start OW-Even measurement to Cell Monitor ASIC 21. At step 503, MCU 20 sends a similar command to Cell Monitor ASIC 22. At step 504, MCU 20 sends the start OW-Even measurement command to Cell Monitor ASIC X. At step 505, upon receiving these commands, the Cell Monitor ASICs stop cell balancing, enable pull-ups on even cells, and start voltage measurement of all cells. At step 506, the system waits for a period (e.g., 100 ms) conversion time. At step 507, MCU 20 sends a command to read the ADC conversion result registers to Cell Monitor ASIC 21. At step 508, MCU 20 sends a similar command to Cell Monitor ASIC 22. At step 509, MCU 20 sends the command to read ADC conversion result registers to Cell Monitor ASIC X. At step 510, Cell Monitor ASIC X sends its ADC conversion results to MCU 20. At step 511, Cell Monitor ASIC 22 sends its ADC conversion results to MCU 20. At step 512, Cell Monitor ASIC 21 sends its ADC conversion results to MCU 20. At step 513, MCU 20 receives and processes the ADC conversion results from ASIC 21. At step 514, MCU 20 receives and processes the ADC conversion results from ASIC 22. At step 515, MCU 20 receives and processes the ADC conversion results from other ASICs X. At step 516, MCU 20 computes ratios and checks thresholds as shown in Table 2, Step 2.

FIG. 5B illustrates an exemplary sequence diagram 520 associated with measurement of pull-up resistance enabled on odd cells for open wire fault detection. At step 521, MCU 20 initiates the open-wire (OW) measurement process for odd cells. At step 522, MCU 20 sends a command to start OW-odd measurement to Cell Monitor ASIC 21. At step 523, MCU 20 sends a similar command to Cell Monitor ASIC 22. At step 524, MCU 20 sends the start OW-odd measurement command to Cell Monitor ASIC X. At step 525, upon receiving these commands, the Cell Monitor ASICs stop cell balancing, enable pull-ups on odd cells, and start voltage measurement of all cells. At step 526, the system waits for a 100 ms conversion time. At step 527, MCU 20 sends a command to read the ADC conversion result registers to Cell Monitor ASIC 21. At step 528, MCU 20 sends a similar command to Cell Monitor ASIC 22. At step 529, MCU 20 sends the command to read ADC conversion result registers to Cell Monitor ASIC X. At step 530, Cell Monitor ASIC X sends its ADC conversion results to MCU 20. At step 531, Cell Monitor ASIC 22 sends its ADC conversion results to MCU 20. At step 532, Cell Monitor ASIC 21 sends its ADC conversion results to MCU 20. At step 533, MCU 20 receives and processes the ADC conversion results from ASIC 21. At step 534, MCU 20 receives and processes the ADC conversion results from ASIC 22. At step 535, MCU 20 receives and processes the ADC conversion results from other ASICs X. At step 536, MCU 20 determines ratios and checks thresholds as shown in Table 2, Step 4.

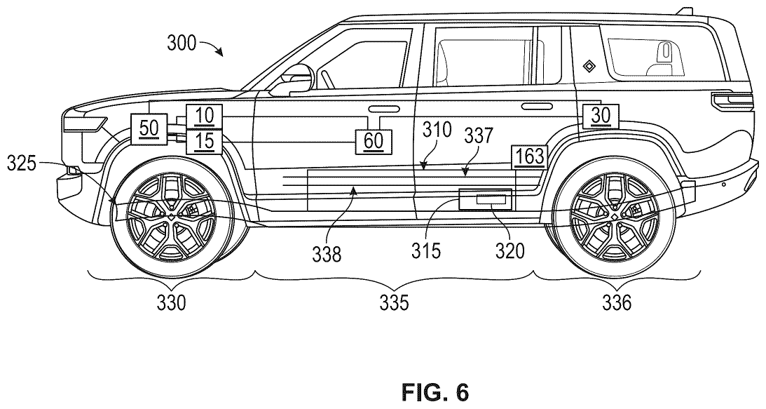

FIG. 6 illustrates an example side view of vehicle 300. As shown, the vehicle 300 may include one or more battery packs, such as high voltage (HV) battery pack 310 (e.g., 450V), which may be located near the center body portion 335 of vehicle 300. HV battery pack 310 may be coupled with one or more electrical systems of the vehicle 300 to provide power to the electrical systems. As further described herein, ECU 10, ECU 15, or ECU 30 may be communicatively connected with or have power distributed with each other and may be functionally redundant for power or other operations of electronic components of vehicle 300. Note one or more battery modules may constitute a pack for the vehicle 300.

In one or more implementations, the vehicle 300 may be an electric vehicle having one or more electric motors that drive the wheels 302 of the vehicle using electric power from HV battery pack 310. In one or more implementations, the vehicle 300 may also, or alternatively, include one or more chemically-powered engines, such as a gas-powered engine or a fuel cell powered motor. For example, electric vehicles can be fully electric or partially electric (e.g., hybrid or plug-in hybrid). In various implementations, the vehicle 300 may be a fully autonomous vehicle that can navigate roadways without a human operator or driver, a partially autonomous vehicle that can navigate some roadways without a human operator or driver or that can navigate roadways with the supervision of a human operator, may be an unmanned vehicle that can navigate roadways or other pathways without any human occupants, or may be a human operated (non-autonomous) vehicle configured for a human operator.

In the example of FIG. 6, the vehicle 300 may be implemented as a truck (e.g., a pickup truck) having a battery pack 310. As shown, HV battery pack 310 may include on or more battery modules 315, which may include one or more battery cells 320 (e.g., cell 101 through cell 104). However, this is merely illustrative and, in other implementations, HV battery pack 310 may be provided without any battery modules 315 (e.g., in a cell-to-pack configuration, pack 100).

As shown in FIG. 6, the vehicle 300 may include a support structure such as a chassis 325 (e.g., a frame, internal frame, or other support structure). The chassis 325 may support various components of the vehicle 300. As shown, the chassis 325 may span a front portion 330 (e.g., a hood or bonnet portion), center body portion 335, and a rear portion 336 (e.g., a trunk, payload, or boot portion) of the vehicle 300 in some implementations. In one or more implementations, HV battery pack 310 may be installed on the chassis 325 (e.g., within one or more of the front portion 330, center body portion 335, or the rear portion 336). As shown, HV battery pack 310 may include or be electrically coupled with one or more one busbars (e.g., one or more current collector elements). In the example of FIG. 6, the vehicle 300 includes a first busbar 337 and a second busbar 338, either or both of which may include electrically conductive material to connect or otherwise electrically couple the battery module(s) 315 or the battery cell(s) s 320 with other electrical components of the vehicle 300 to provide electrical power to various systems or components of the vehicle 300.

In other implementations, the vehicle 300 may implemented as another type of electric truck, an electric delivery van, an electric automobile, an electric car, an electric motorcycle, an electric scooter, an electric passenger vehicle, an electric passenger or commercial truck, a hybrid vehicle, or other vehicles such as sea or air transport vehicles, planes, helicopters, submarines, boats, or drones, and/or any other movable apparatus having a battery pack 310 (e.g., that powers the propulsion or drive components of the moveable apparatus).

A method, system, or apparatus may be configured to receive, at a first period, a first voltage measurement of a second battery cell, wherein the second battery cell has pull-up resistance is enabled and the second battery cell is an even cell; receive, at the first period, a second voltage measurement of a first battery cell, wherein the first battery cell has pull-up resistance disabled and the first battery cell is an odd cell; determining that the first voltage measurement and the second voltage measurement has a first relationship (e.g., ratio) within a first threshold; receive, at a first period, a first voltage measurement of a second battery cell, wherein the second battery cell has pull-up resistance disabled and the second battery cell is an even cell; receive, at the first period, a second voltage measurement of a first battery cell, wherein the first battery cell has pull-up resistance enabled and the first battery cell is an odd cell; determine that the first voltage measurement and the second voltage measurement has a second relationship (e.g., ratio) within a second threshold; and based on the determining that the first relationship (e.g., ratio) is within the first threshold or the second relationship (e.g., ratio) is within the second threshold, send an indication of open wire fault detection. Based on the indication of the open wire default, the vehicle may send an alert or automatically be placed in a safe mode (e.g., stop vehicle driving functions, shutoff one or more loads, or the like). After an indication of an open wire fault, there may be different actions that may be taken, such sending an audio, visual, or haptic alert to the driver, determine if the vehicle is in a safe operating condition, or halt the vehicle within a certain time frame, among other things. All combinations in this paragraph (including the removal or addition of steps) as well as the different methods (e.g., FIG. 2-FIG. 5B) are contemplated.

A system, method, or apparatus for detecting and responding to open wire faults in a battery pack may be provided. In an example, the system may include a plurality of battery cells arranged in series; one or more application-specific integrated circuits (ASICs) coupled with the battery cells; and a microcontroller unit. The microcontroller unit may be configured to obtain a first voltage measurement from an even battery cell of the plurality of battery cells with pull-up resistance enabled at a first time; obtain a second voltage measurement from an odd battery cell of the plurality of battery cells with pull-up resistance disabled at the first time; determine a relationship (e.g., ratio) between the first voltage measurement and the second voltage measurement; and generate an open wire fault alert when the relationship (e.g., ratio) exceeds a predetermined threshold. All combinations (including the removal or addition of steps) in this paragraph or above paragraphs such as the different methods (e.g., FIG. 2-FIG. 5B) are contemplated in a manner that is consistent with the other portions of the detailed description.

A method, system, or apparatus for detecting and responding to open wire faults in a battery system may be provided. In an example, a method may include receiving, at a first period, a first voltage measurement of a second battery cell, wherein the second battery cell has pull-up resistance enabled and is an even cell; receiving, at the first period, a second voltage measurement of a first battery cell, wherein the first battery cell has pull-up resistance disabled and is an odd cell; determining that the first voltage measurement and the second voltage measurement has a first relationship (e.g., ratio) within a first threshold; and sending a first indication of open wire fault detection, based on the determining that the first relationship (e.g., ratio) is within the first threshold. The first battery cell and second battery cell may be measured using dedicated analog-to-digital converters. The method may further include transmitting instructions to place a vehicle in a safe operating condition based on the first indication of the open wire fault detection. The sending of the first indication may include transmitting at least one of an audio alert, a visual alert, or a haptic alert. The threshold value may include a range between 0.8 and 1.2. The first indication may be sent to a component of an electronic control unit (ECU) of an electric vehicle. The first battery cell and the second battery cell may be part of a battery pack of an electric vehicle. The first threshold may be determined based on a load profile of a battery system associated with the battery pack. The method may further include receiving, at a second period, a third voltage measurement of the second battery cell with pull-up resistance disabled; receiving, at the second period, a fourth voltage measurement of the first battery cell with pull-up resistance enabled; determining that a second relationship (e.g., ratio) of the third voltage measurement and the fourth voltage measurement is within a second threshold; and sending a second indication of an open wire fault detection based on determining that the second relationship (e.g., ratio) is within the second threshold. The receiving of the first voltage measurement or the second voltage measurement may be based on detecting that cell balancing operations have ceased. All combinations (including the removal or addition of steps) in this paragraph are contemplated in a manner that is consistent with the other portions of the detailed description.

The methods, systems, or apparatuses disclosed herein may be incorporated into electric vehicles or other devices. The circuit blocks disclosed herein may be distributed with or combined with one or more ECUs or other devices. The methods, systems, or apparatuses disclosed herein may be incorporated into products, such as various feature specific or zone specific electronic control units (ECUs).

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

The predicate words “configured to”, “operable to”, and “programmed to” do not imply any particular tangible or intangible modification of a subject, but, rather, are intended to be used interchangeably. In one or more implementations, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

The various techniques described herein may be implemented in connection with hardware, firmware, software or, where appropriate, combinations thereof. Such hardware, firmware, and software may reside in apparatuses located at various nodes of a communication network. The apparatuses may operate singly or in combination with each other to effectuate the methods described herein. In addition, the use of the word “or” is generally used inclusively unless otherwise provided herein. The methods herein may be implemented locally or remotely or in combinations of local and remote systems, configured to perform a function that can be implemented using software, hardware, or combinations thereof in the above-described environments.

The word “exemplary” is used herein to mean “serving as an example, instance, or illustration”. Any embodiment described herein as “exemplary” or as an “example” is not necessarily to be construed as preferred or advantageous over other embodiments. Furthermore, to the extent that the term “include”, “have”, or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more”. Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. A method comprising:
receiving, at a first period, a first voltage measurement of a second battery cell, wherein the second battery cell has pull-up resistance is enabled and the second battery cell is an even cell;
receiving, at the first period, a second voltage measurement of a first battery cell, wherein the first battery cell has the pull-up resistance disabled and the first battery cell is an odd cell;
determining that the first voltage measurement and the second voltage measurement has a first ratio within a first threshold; and
sending a first indication of open wire fault detection, based on the determining that the first ratio is within the first threshold.

2. The method of claim 1, wherein the first battery cell and second battery cell are measured using dedicated analog-to-digital converters.

3. The method of claim 1, further comprising transmitting instructions to place a vehicle in a safe operating condition based on the first indication of the open wire fault detection, wherein the safe operating condition comprises shutoff of one or more loads.

4. The method of claim 1, wherein the sending of the first indication comprises transmitting an audio alert, a visual alert, or a haptic alert.

5. The method of claim 1, wherein the threshold value comprises a range between 0.8 and 1.2.

6. The method of claim 1, wherein the first indication is sent to a component of an electronic control unit (ECU) of an electric vehicle.

7. The method of claim 1, wherein the first battery cell and the second battery cell are part of a battery pack of an electric vehicle.

8. The method of claim 7, wherein the first threshold is determined based on a load profile of a battery system associated with the battery pack.

9. The method of claim 1, further comprising:
receiving, at a second period, a third voltage measurement of the second battery cell with pull-up resistance disabled;
receiving, at the second period, a fourth voltage measurement of the first battery cell with the pull-up resistance enabled;
determining that a second ratio of the third voltage measurement and the fourth voltage measurement is within a second threshold; and
sending a second indication of an open wire fault detection based on determining that the second ratio is within the second threshold.

10. An apparatus configured to:
receive, at a first period, a first voltage measurement of a second battery cell, wherein the second battery cell has pull-up resistance is enabled and the second battery cell is an even cell;
receive, at the first period, a second voltage measurement of a first battery cell, wherein the first battery cell has the pull-up resistance disabled and the first battery cell is an odd cell;
determine that the first voltage measurement and the second voltage measurement has a first ratio within a first threshold; and
send a first indication of open wire fault detection, based on the determining that the first ratio is within the first threshold.

11. The apparatus of claim 10, wherein the first battery cell and second battery cell are measured using dedicated analog-to-digital converters.

12. The apparatus of claim 10, further comprising transmitting instructions to place a vehicle in a safe operating condition based on the first indication of the open wire fault detection.

13. The apparatus of claim 10, wherein the sending of the first indication comprises transmitting an audio alert, a visual alert, or a haptic alert.

14. The apparatus of claim 10, wherein the threshold value comprises a range between 0.8 and 1.2.

15. The apparatus of claim 10, wherein the first indication is sent to a component of an electronic control unit (ECU) of an electric vehicle.

16. The apparatus of claim 10, wherein the first battery cell and the second battery cell are part of a battery pack of an electric vehicle.

17. The apparatus of claim 16, wherein the first threshold is determined based on a load profile of a battery system associated with the battery pack.

18. The apparatus of claim 10, further comprising:
receive, at a second period, a third voltage measurement of the second battery cell with pull-up resistance disabled;
receive, at the second period, a fourth voltage measurement of the first battery cell with the pull-up resistance enabled;
determine that a second ratio of the third voltage measurement and the fourth voltage measurement is within a second threshold; and
send a second indication of an open wire fault detection based on determining that the second ratio is within the second threshold.

19. The apparatus of claim 10, wherein the apparatus comprises a microcontroller unit.

20. A system for detecting open wire faults in a battery pack, comprising:
a plurality of battery cells arranged in series;
one or more application-specific integrated circuits (ASICs) coupled to the battery cells; and
a microcontroller unit configured to:
obtain a first voltage measurement from an even battery cell of the plurality of battery cells with pull-up resistance enabled at a first period;
obtain a second voltage measurement from an odd battery cell of the plurality of battery cells with the pull-up resistance disabled at the first period;
determine a ratio between the first voltage measurement and the second voltage measurement; and
generate an open wire fault alert when the ratio exceeds a predetermined threshold.
